(19) United States
(12) Patent Application Publication
(10) Pub. No.: US 2020/0095670 A1
(43) Pub. Date: Mar. 26, 2020

(54) METHOD FOR FORMING ADHEREND WITH OPTICAL THIN FILM

(71) Applicant: DISCO CORPORATION, Tokyo (JP)

(72) Inventor: Tasuku KOYANAGI, Tokyo (JP)

(21) Appl. No.: 16/567,083

(22) Filed: Sep. 11, 2019

(30) Foreign Application Priority Data
Sep. 25, 2018 (JP) 2018-179103

(51) Int. Cl. C23C 14/54; H01L 21/56; C23C 14/34; C09J 9/02; G02B 1/10

(52) U.S. Cl. CPC C23C 14/54; H01L 21/56; C09J 2203/326; C09J 9/02; G02B 1/10; C23C 14/34

(57) ABSTRACT

A method for forming an adherend with an optical thin film through sticking the optical thin film to the adherend is provided. The method includes a substrate preparation step of preparing a substrate over which the optical thin film is formed with the intermediary of a bonding layer, a sticking step of sticking the adherend with lower heat resistance compared with quartz glass to the side of the optical thin film of the substrate, a bonding layer breaking step of breaking the bonding layer through carrying out irradiation with a laser beam with such a wavelength as to be transmitted through the substrate and be absorbed by the bonding layer from the surface of the substrate on the opposite side to the surface over which the optical thin film is formed, and a separating step of separating the adherend to which the optical thin film is stuck and the substrate.

### BACKGROUND OF THE INVENTION

### Field of the Invention

The present invention relates to a method for forming an adherend with an optical thin film through sticking the optical thin film to a surface of the adherend.

### Description of the Related Art

In the case of forming a metal thin film on a substrate, it is general to form the metal thin film by a method such as a sputtering method (refer to Japanese Patent Laid-Open No. 2006-330485) or an vapor deposition method (refer to Japanese Patent Laid-Open No. Hei 8-122503). Furthermore, when the substrate on which the metal thin film is formed is used as an optical element, it is general that this substrate is composed of quartz glass. However, there is a demand to use a material with lower specific gravity than quartz glass (for example, resin material) for weight reduction and cost reduction.

### SUMMARY OF THE INVENTION

The material with lower specific gravity than quartz glass has a lower melting point compared with quartz glass in general and therefore, has lower heat resistance compared with quartz glass. In the case of forming a thin film on the substrate formed of such a material with low heat resistance, there is a problem that the substrate itself gets deformed due to heat applied in a step of sputtering or the like or heat generated in the step and therefore, it is impossible to properly form the thin film on the substrate. The present invention is made in view of this problem and intends to provide a method for forming a thin film on an object formed of a material with lower heat resistance compared with quartz glass without causing deformation of this object due to heat.

In accordance with an aspect of the present invention, there is provided a method for forming an adherend with an optical thin film through sticking the optical thin film to the adherend. The method includes a substrate preparation step of preparing a substrate over which the optical thin film is formed with the intermediary of a bonding layer, a sticking step of sticking the adherend with lower heat resistance compared with quartz glass to the side of the optical thin film of the substrate after the substrate preparation step, a bonding layer breaking step of breaking the bonding layer through carrying out irradiation with a laser beam with such a wavelength as to be transmitted through the substrate and be absorbed by the bonding layer from a surface of the substrate on the opposite side to a surface over which the optical thin film is formed after the sticking step, and a separating step of separating the adherend to which the optical thin film is stuck and the substrate after the bonding layer breaking step.

Preferably, the adherend is formed of a resin.

In the method for forming an adherend with an optical thin film through sticking the optical thin film to the adherend according to the aspect of the present invention, after sticking, to the adherend, the side of the optical thin film of the substrate over which the optical thin film is formed with the intermediary of the bonding layer, irradiation with the laser beam is carried out to break the bonding layer. Thereby, the coupling between the optical thin film and the substrate is released and therefore, the optical thin film is transferred to the adherend. In the bonding layer breaking step, the laser beam is focused on the bonding layer and therefore, only the bonding layer is broken. Moreover, heat is hardly applied to the adherend. For this reason, in the bonding layer breaking step, even an object with lower heat resistance compared with quartz glass is not deformed due to heat.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1A is a perspective view depicting one example of an adherend to which an optical thin film is to be stuck;

FIG. 1B is a perspective view of a layer-stacking body prepared in a substrate preparation step (S10);

FIG. 2A is a diagram depicting a sticking step (S20) of sticking the side of the optical thin film of a substrate to a prism;

FIG. 2B is a perspective view of a prism unit after the sticking step (S20);

FIG. 3 is a perspective view of a laser processing apparatus;

FIG. 4 is a partial cross-sectional side view depicting a bonding layer breaking step (S30);

FIG. 5A is a diagram depicting a separating step (S40) of separating the prism and the substrate;

FIG. 5B is a perspective view of the prism after the separating step (S40);

FIG. 6 is a flowchart of a first embodiment depicting a method for forming a prism with an optical thin film through sticking the optical thin film to the prism; and

FIG. 7 is a partial cross-sectional side view depicting the bonding layer breaking step (S30) using a holding jig according to a second embodiment.

### DETAILED DESCRIPTION OF THE PREFERRED EMBODIMENT

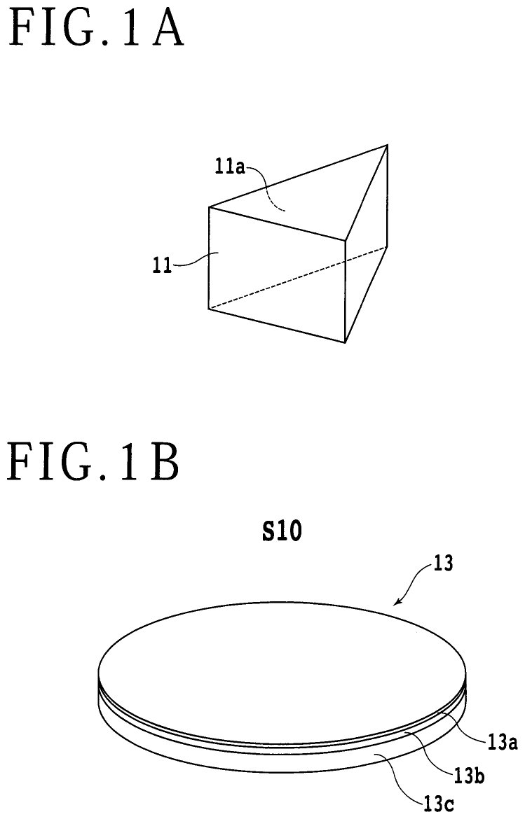

An embodiment according to one aspect of the present invention will be described with reference to the accompanying drawings. FIG. 1A is a perspective view depicting one example of an adherend to which an optical thin film is to be stuck. The adherend of the present embodiment is composed of a material with lower heat resistance compared with quartz glass. In general, quartz glass is softened at about 1700° C. and is melted at 2000° C. or higher. In contrast, the adherend of the present embodiment is softened or melted at a predetermined temperature equal to or lower than 1700° C., for example. The adherend of the present embodiment is formed of a resin such as polyethylene (PE), polypropylene (PP), or polyvinyl chloride (PVC) melted at a predetermined temperature from about 80° C. to about 250° C. However, the material of the adherend is not limited to PE, PP, and PVC and may be formed of another resin.

By forming the adherend by a resin, the weight of the adherend to which an optical thin film is stuck (i.e. optical element) can be set to about half or smaller compared with the case in which the adherend is formed of quartz glass. This optical element is, for example, used as a component inside a camera and therefore, using the adherend made of a resin can reduce the weight of the camera itself. Moreover, the cost necessary for the resin material, processing thereof, and so forth is generally inexpensive compared with the case of quartz glass and therefore, the adherend made of a resin is manufactured at a lower cost compared with the adherend of quartz glass. As depicted in FIG. 1A, the adherend of the present embodiment is a prism 11. However, the adherend is not limited to the prism 11. The adherend may be a transparent plate material that becomes a mirror, half-mirror, dichroic mirror, or the like when an optical thin film is stuck thereto. Furthermore, the adherend may be a semiconductor substrate on which a circuit of complementary metal oxide semiconductor (CMOS) or the like is formed.

To one surface 11a of the prism 11, an optical thin film 13a (see FIG. 1B) disposed on a substrate 13c is stuck. The optical thin film 13a of the present embodiment is a circular thin film having a larger area than the one surface 11a of the prism 11. The thickness of the optical thin film 13a of the present embodiment is 1 μm. However, the optical thin film 13a may have a predetermined thickness that is smaller than 1 μm or exceeds 1 μm. The optical thin film 13a is a thin film formed of gold (Au) or aluminum (Al), for example. In this case, when the optical thin film 13a is stuck to the one surface 11a of the prism 11, the one surface 11a of the prism 11 functions as a mirror.

Alternatively, the optical thin film 13a is a thin film formed of magnesium fluoride (MgF₂), for example. If the MgF₂ thin film has a predetermined optical thickness with which light reflected at the surface of the MgF₂ thin film and reflected light from the interface between the MgF₂ thin film and the prism 11 interfere to weaken each other, the MgF₂ thin film stuck to the one surface 11a of the prism 11 functions as an antireflection film. Alternatively, the optical thin film 13a is, for example, a thin film that is formed of tin (Sn) or silver (Ag) and has a predetermined thickness smaller than the thickness when the one surface 11a of the prism 11 is used as the above-described mirror. In this case, when the optical thin film 13a is stuck to the one surface 11a of the prism 11, the one surface 11a of the prism 11 functions as a half mirror or beam splitter. Besides, various materials may be used as the optical thin film 13a. The optical thin film 13a is bonded to the substrate 13c with the intermediary of a bonding layer 13b (see FIG. 1B). The bonding layer 13b is formed of a material with high heat resistance at such a level as to be capable of withstanding heat applied or generated in a forming step of the optical thin film 13a.

The bonding layer 13b of the present embodiment is formed of heat-curable polyimide (PI) that is not melted even at a temperature equal to or higher than 500° C. However, the material of the bonding layer 13b is not limited to polyimide and may be another material. The bonding layer 13b has a thickness of about 1 μm to 20 μm and more preferably, a thickness of at least 1 μm and at most 5 μm. The optical thin film 13a is formed over the substrate 13c with a circular disc shape with the intermediary of the bonding layer 13b and is supported and fixed by the substrate 13c. The optical thin film 13a, the bonding layer 13b, and the substrate 13c form a layer-stacking body 13. The substrate 13c of the present embodiment is a transparent member that is formed of sapphire with substantially the same diameter as the optical thin film 13a and allows a laser beam in the ultraviolet band to be described later to be transmitted therethrough.

FIG. 1B is a perspective view of the layer-stacking body 13 prepared in the substrate preparation step (S10). In the substrate preparation step (S10), first, the bonding layer 13b is formed on a flat surface of the substrate 13c by using an applying apparatus (not depicted) or the like. Next, the optical thin film 13a is formed on the surface of the bonding layer 13b on the opposite side to the substrate 13c by using a sputtering apparatus (not depicted) or the like. Thereby, the layer-stacking body 13 in which the substrate 13c, the bonding layer 13b, and the optical thin film 13a are stacked in this order is formed. After the substrate preparation step (S10), the optical thin film 13a of the layer-stacking body 13 and the one surface 11a of the prism 11 are stuck to each other (sticking step (S20)). In the sticking step (S20) of the present embodiment, a glue agent formed of a resin or the like is applied to the one surface 11a of the prism 11.

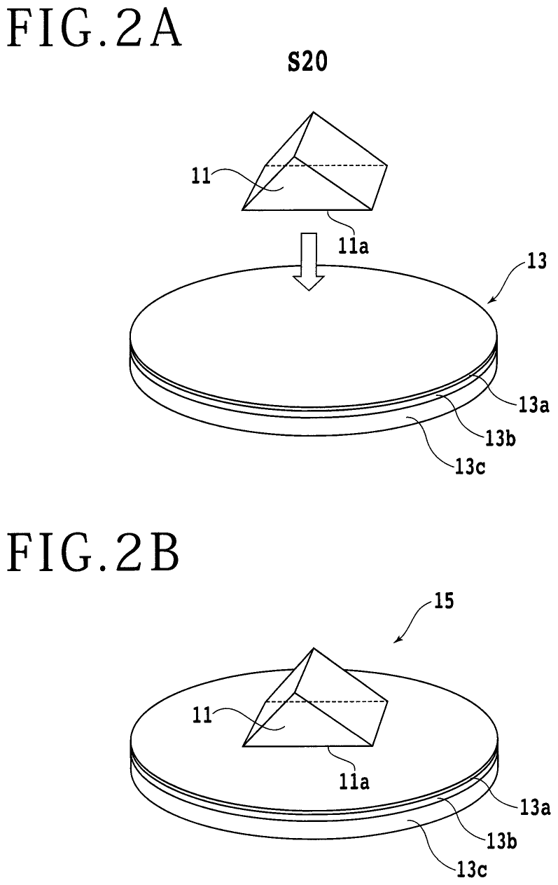

The glue agent is composed of a transparent material that does not absorb light incident on the prism 11 and is applied to the one surface 11a of the prism 11 extremely thinly. For example, the glue agent is selected from heat-curable resins of acrylic resin, silicone resin, polyurethane, and so forth and is applied to yield a thickness of several nanometers to several micrometers. Then, the one surface 11a of the prism 11 to which the glue agent has been applied is stuck to the side of the optical thin film 13a of the layer-stacking body 13. Thereby, a prism unit 15 (see FIG. 2B) in which the one surface 11a of the prism 11 is stuck to the substrate 13c with the intermediary of the bonding layer 13b and the optical thin film 13a is formed. FIG. 2A is a diagram depicting the sticking step (S20) of sticking the side of the optical thin film 13a of the substrate 13c to the prism 11 and FIG. 2B is a perspective view of the prism unit 15 after the sticking step (S20).

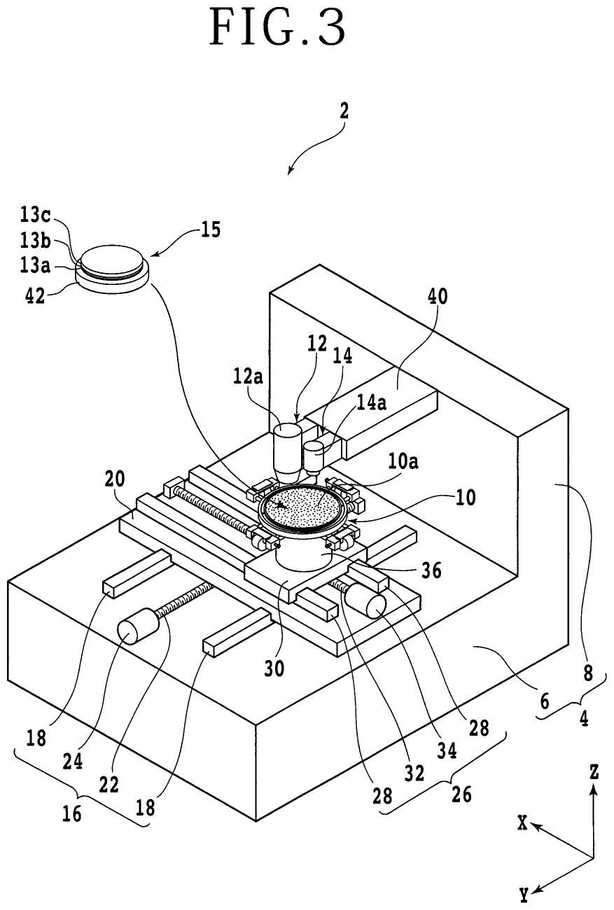

After the sticking step (S20), the layer-stacking body 13 is irradiated with a laser beam by using a laser processing apparatus 2 and the bonding layer 13b of the layer-stacking body 13 is broken (bonding layer breaking step (S30)). FIG. 3 is a perspective view of the laser processing apparatus 2 used in the bonding layer breaking step (S30). As depicted in FIG. 3, the laser processing apparatus 2 includes a pedestal 4 that supports the respective structures. The pedestal 4 includes a base part 6 with a rectangular parallelepiped shape and a wall part 8 that extends upward at the rear end of the base part 6. A chuck table 10 is disposed over the upper surface of the base part 6.

A Y-axis movement unit 16 that moves the chuck table 10 in a Y-axis direction (indexing feed direction) is disposed below the chuck table 10. The Y-axis movement unit 16 includes a pair of Y-axis guide rails 18 that are fixed to the upper surface of the base part 6 and are parallel to the Y-axis direction. A Y-axis movement table 20 is slidably disposed on the Y-axis guide rails 18. A nut part (not depicted) is disposed on the back surface side (lower surface side) of the Y-axis movement table 20 and a Y-axis ball screw 22 parallel to the Y-axis guide rails 18 is coupled to this nut part in a rotatable form. A Y-axis pulse motor 24 is joined to one end part of the Y-axis ball screw 22. When the Y-axis ball screw 22 is rotated by the Y-axis pulse motor 24, the Y-axis movement table 20 moves in the Y-axis direction along the Y-axis guide rails 18.

An X-axis movement unit 26 that moves the chuck table 10 in an X-axis direction (processing feed direction) orthogonal to the Y-axis direction is disposed on the front surface side (upper surface side) of the Y-axis movement table 20. The X-axis movement unit 26 includes a pair of X-axis guide rails 28 that are fixed to the upper surface of the Y-axis movement table 20 and are parallel to the X-axis direction. An X-axis movement table 30 is slidably disposed on the X-axis guide rails 28. A nut part (not depicted) is disposed on the back surface side (lower surface side) of the X-axis movement table 30 and an X-axis ball screw 32 parallel to the X-axis guide rails 28 is coupled to this nut part in a rotatable form. An X-axis pulse motor 34 is joined to one end part of the X-axis ball screw 32. When the X-axis ball screw 32 is rotated by the X-axis pulse motor 34, the X-axis movement table 30 moves in the X-axis direction along the X-axis guide rails 28.

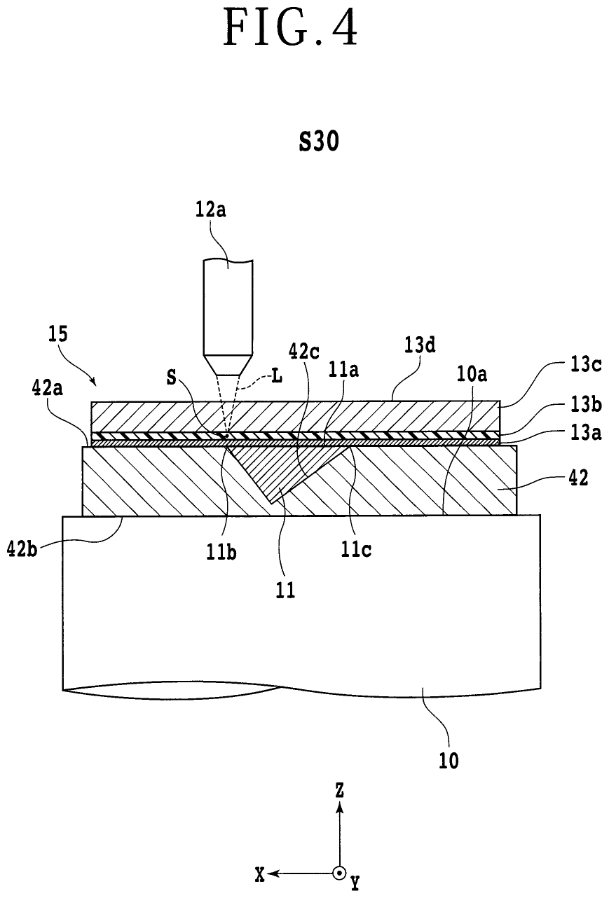

A support base 36 is disposed on the front surface side (upper surface side) of the X-axis movement table 30. The chuck table 10 is disposed at the upper part of the support base 36. The chuck table 10 is joined to a rotational drive source (not depicted) disposed on the lower side and can rotate around a Z-axis. A holding jig 42 is set on the front surface of the chuck table 10. The front surface of the chuck table 10 serves as a holding surface 10a that sucks and holds the holding jig 42. A negative pressure of a suction source (not depicted) acts on this holding surface 10a through a flow path (not depicted) formed inside the chuck table 10 and a suction force that sucks a back surface 42b (see FIG. 4) of the holding jig 42 is generated.

The holding jig 42 is formed of a stainless steel, resin, or the like. In the case of forming the holding jig 42 by a resin, for example, a 3D printer can be used. When a 3D printer is used, the holding jig 42 can be manufactured in a shorter period compared with the case of manufacturing the holding jig 42 by cutting stainless steel. The holding jig 42 has one recess part 42c (see FIG. 4) with a shape corresponding to one prism 11 in a front surface 42a (see FIG. 4) on the opposite side to the back surface 42b. When the prism unit 15 is disposed on the holding jig 42 in such a manner that the optical thin film 13a of the prism unit 15 comes into contact with the front surface 42a of the holding jig 42, the prism 11 fits into the recess part 42c of the holding jig 42 and the one surface 11a of the prism 11 becomes flush with the front surface 42a of the holding jig 42. In this manner, the prism unit 15 is held by the holding jig 42.

A positioning part (for example, a positioning pin) that restricts movement of the prism unit 15 and accurately settles the position of the prism unit 15 may be disposed on the front surface 42a of the holding jig 42. For example, the positioning part is disposed at two points in the front surface 42a or three points that are not located on the same straight line in the front surface 42a. A support arm 40 that extends toward the front side is disposed on the front surface of the upper part of the wall part 8 and a processing head 12a of a laser beam irradiation unit 12 is disposed at the tip part of this support arm 40 in such a manner as to be located above the chuck table 10 and be opposed to the holding surface 10a. The laser beam irradiation unit 12 can emit a laser beam L substantially perpendicularly from the processing head 12a toward the prism unit 15 on the holding jig 42 held by the holding surface 10a.

The laser beam irradiation unit 12 may have a galvanometer scanner that carries out scanning with the laser beam L incident from a laser oscillator in the X-axis and Y-axis directions and a telecentric fθ lens disposed on the side toward which the laser beam L is emitted from the galvanometer scanner, instead of the processing head 12a that emits the laser beam L to the holding surface 10a substantially perpendicularly. The galvanometer scanner has an X-scan mirror for carrying out scanning with the laser beam L along the X-axis direction and a Y-scan mirror for carrying out scanning with the laser beam L along the Y-axis direction. Furthermore, the laser beam L emitted from the galvanometer scanner is incident on the holding surface 10a substantially perpendicularly through the telecentric fθ lens.

The prism unit 15 is irradiated with the laser beam L from a surface 13d of the substrate 13c on the opposite side to the surface over which the optical thin film 13a is formed (see FIG. 4). The laser beam L has such a wavelength as to be transmitted through the substrate 13c and be absorbed by the bonding layer 13b. The laser beam L of the present embodiment has a predetermined wavelength between 257 nm and 355 nm. It is preferable for the laser beam L to have such a wavelength as to be transmitted through the optical thin film 13a in order to reduce or eliminate damage to the optical thin film 13a. An imaging head 14a of an imaging unit 14 that images the prism unit 15 held by the holding surface 10a is disposed at a position adjacent to the laser beam irradiation unit 12. For example, the imaging unit 14 has a light source unit that irradiates the prism unit 15 with a visible light beam and an imaging element that receives reflected light or the like from the prism unit 15.

The imaging unit 14 images the prism 11 located on the holding jig 42 by imaging, from above, the prism unit 15 irradiated with the visible light beam similarly from above. An image obtained by the imaging by the imaging unit 14 is used, for example, for position alignment between the prism unit 15 and the processing head 12a. The wavelength of light that can be transmitted through the substrate 13c differs depending on the material of the substrate 13c. Therefore, light other than the visible light beam, such as an infrared ray, may be used according to the material of the substrate 13c. For example, the light source unit may emit light other than the visible light beam and the imaging element may receive reflected light of this light other than the visible light beam.

Next, the bonding layer breaking step (S30) will be described by using FIG. 4. FIG. 4 is a partial cross-sectional side view depicting the bonding layer breaking step (S30). In the bonding layer breaking step (S30), first, the optical thin film 13a of the prism unit 15 and the front surface 42a of the holding jig 42 are brought into tight contact with each other in such a manner that the prism 11 fits into the recess part 42c of the holding jig 42, and the holding jig 42 is disposed on the holding surface 10a. Next, the suction source is actuated to suck and hold the side of the back surface 42b of the holding jig 42. Thereby, the prism unit 15 is fixed by the chuck table 10 with the intermediary of the holding jig 42. Then, while the laser beam L is emitted from the processing head 12a, the processing head 12a and the chuck table 10 are relatively moved and a region in the bonding layer 13b corresponding to the one surface 11a of the prism 11 is broken by ablation. The region in the bonding layer 13b corresponding to the one surface 11a of the prism 11 is, for example, a region with the same shape and same area as the one surface 11a of the prism 11.

The region in the bonding layer 13b corresponding to the one surface 11a of the prism 11 may be broken by ablation by using a galvanometer scanner and a telecentric fθ lens instead of the processing head 12a as described above. The position of a focal spot S of the laser beam L in the Z-axis direction is adjusted by a condensing lens (not depicted) or the like in the processing head 12a. In the present embodiment, the position of the focal spot S in the Z-axis direction is adjusted to a position in the bonding layer 13b. By relatively moving the processing head 12a and the chuck table 10 along the X-axis direction in the state in which the position of the focal spot S in the Z-axis direction is kept at the position in the bonding layer 13b, the focal spot S of the laser beam L moves in the bonding layer 13b along the X-axis direction.

At this time, the focal spot S moves from one side 11b in the one surface 11a of the prism 11 to another side 11c opposed to this one side 11b in the X-axis direction. Various conditions of the laser beam L are adjusted in such a manner that two focal spots S adjacent in the X-axis direction partly overlap. After the irradiation with the laser beam L along one straight line in the X-axis direction ends, the chuck table 10 is moved in the indexing feed direction and the bonding layer 13b corresponding to the range from the one side 11b to the one side 11c is irradiated with the laser beam L along another straight line in the X-axis direction similarly again. At this time, it is desirable that the focal spot S moved along the above-described other straight line partly overlaps with the focal spot S moved along the above-described one straight line, in the indexing feed direction.

Subsequently, by carrying out irradiation with the laser beam L while sequentially moving the chuck table 10 in the indexing feed direction and the processing feed direction, the bonding layer 13b in the range corresponding to the one surface 11a is subjected to ablation. In the present embodiment, the range in the bonding layer 13b with the same shape and same area as the one surface 11a of the prism 11 is subjected to ablation based on the above-described procedure. However, a range in the bonding layer 13b with a size larger than the one surface 11a of the prism 11 by about 1 mm to 2 mm may be subjected to ablation. By carrying out the ablation of the bonding layer 13b in a range wider than the one surface 11a of the prism 11, a defect or the like of the optical thin film 13a in the one surface 11a can be reduced in the separating step (S40) to be described later.

The laser processing conditions in the bonding layer breaking step (S30) are, for example, set as follows.

Repetition frequency: 50 kHz to 200 kHz

Average output power: 0.1 W to 2 W

Pulse width: 1 ps to 20 ps

Pulse energy: 0.5 μJ to 10 μJ

Spot diameter: 10 μm to 50 μm

Processing feed rate: 50 mm/s to 100 mm/s

In the bonding layer breaking step (S30) according to the present embodiment, only the bonding layer 13b is broken and heat is hardly applied to the prism 11. For this reason, the prism 11 is not deformed due to heat although the prism 11 is formed of a material with lower heat resistance compared with quartz glass. After the bonding layer breaking step (S30), the prism 11 to which the optical thin film 13a is stuck and the substrate 13c are separated (separating step (S40)). In the separating step (S40) of the present embodiment, first, the operation of the suction source is stopped to deactivate the sucking and holding of the holding jig 42 by the chuck table 10. Thereafter, an operator takes out the holding jig 42 and the prism unit 15 from the chuck table 10 and turns the holding jig 42 and the prism unit 15 upside down to make the state in which the holding jig 42 is supported by the layer-stacking body 13. Moreover, thereafter, the holding jig 42 is removed from the layer-stacking body 13 and subsequently, the prism 11 is taken out from the layer-stacking body 13.

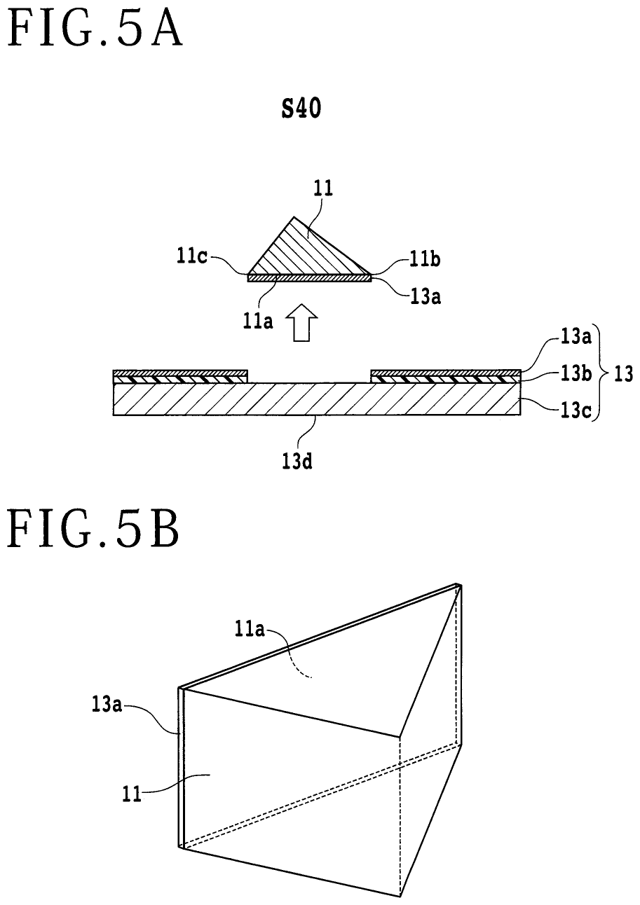

The bonding layer 13b in the range opposed to the one surface 11a of the prism 11 is broken, whereas the bonding layer 13b in the range that is not opposed to the one surface 11a is not broken and remains in tight contact with the optical thin film 13a and the substrate 13c. For this reason, when the prism 11 is taken out, the region opposed to the one surface 11a in the optical thin film 13a is separated from the other region in the optical thin film 13a, with the outer circumference of the one surface 11a being the boundary. FIG. 5A is a diagram depicting the separating step (S40) of separating the prism 11 and the substrate 13c. After the separating step (S40), the prism 11 with the optical thin film 13a is cleaned (cleaning step (S50)). In the present embodiment, a solution of propyleneglycol monomethyl ether acetate (PGMEA) or the like is poured into a cleaning container (not depicted) and the prism 11 with the optical thin film 13a is immersed in this solution for about 20 minutes.

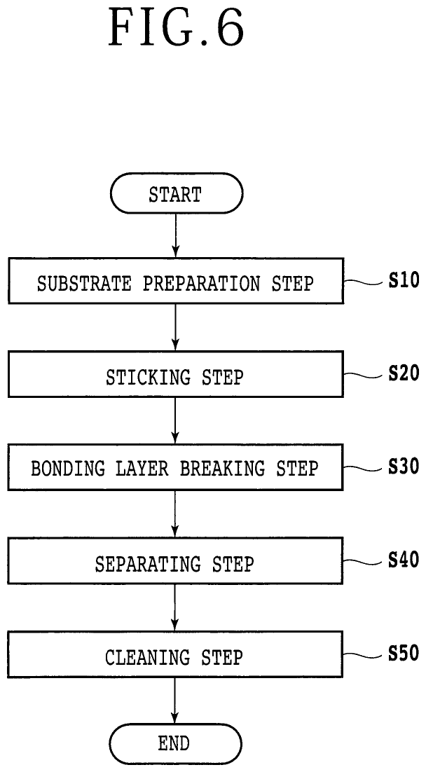

Thereby, the prism 11 with the optical thin film 13a is cleaned and a residual of the bonding layer 13b and so forth on the surface of the optical thin film 13a located on the opposite side to the one surface 11a of the prism 11 are removed. In this manner, the prism 11 in which the optical thin film 13a has been transferred from the layer-stacking body 13 onto the one surface 11a can be obtained. FIG. 5B is a perspective view of the prism 11 after the separating step (S40). FIG. 6 is a flowchart of the first embodiment showing the method for forming the prism 11 with the optical thin film 13a through sticking the optical thin film 13a to the prism 11. The exposed surface of the optical thin film 13a is switched through transferring this optical thin film 13a to the prism 11 through the bonding layer breaking step (S30) and the separating step (S40) after the optical thin film 13a is formed over the substrate 13c in the substrate preparation step (S10).

In general, in the case of forming the optical thin film 13a in contact with the bonding layer 13b by a sputtering method, the surface of the optical thin film 13a on the side of the bonding layer 13b is flatter (for example, arithmetic average roughness (Ra) is lower) compared with the front surface of the optical thin film 13a located on the opposite side to the bonding layer 13b. For this reason, in the present embodiment, a step of polishing and planarizing the front surface of the optical thin film 13a after the optical thin film 13a is formed by the sputtering method in the substrate preparation step (S10) is omitted. This can simplify the work step and shorten the work time. Furthermore, the above-described separating step (S40) may be carried out by another procedure. For example, after the operation of the suction source is stopped, the layer-stacking body 13 may be removed from the holding jig 42 with the holding jig 42 remaining placed on the chuck table 10 and thereafter the prism 11 with the optical thin film 13a left in the recess part 42c of the holding jig 42 may be taken out.

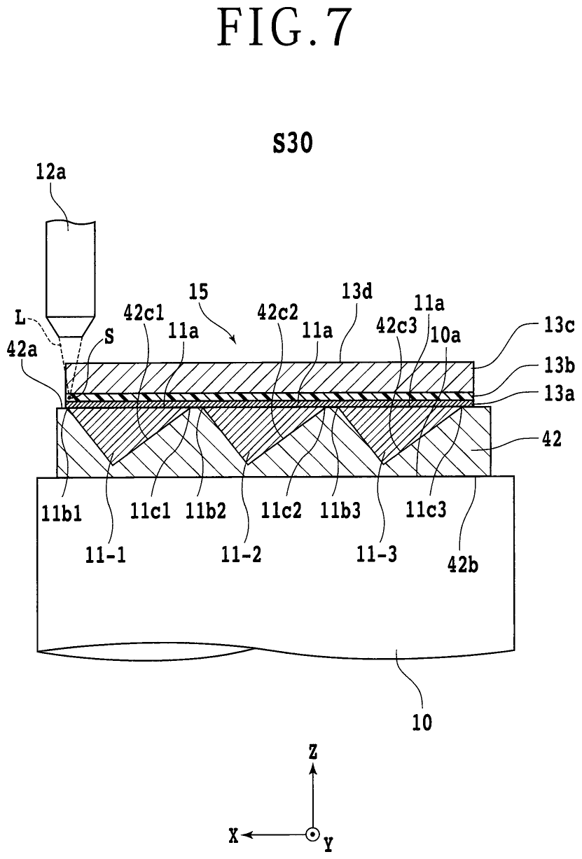

Next, a second embodiment will be described. FIG. 7 is a partial cross-sectional side view depicting the bonding layer breaking step (S30) using a holding jig 42 according to the second embodiment. In the second embodiment, plural prisms 11-1, 11-2, and 11-3 are stuck in contact with the optical thin film 13a in such a manner as to line up along a predetermined direction and the holding jig 42 has the same number of recess parts 42c1, 42c2, and 42c3 as the prisms 11, made to line up along the predetermined direction. In the second embodiment, a prism unit 15 with the plural prisms 11-1, 11-2, and 11-3 may be formed by the same procedures as the substrate preparation step (S10) and the sticking step (S20) of the first embodiment.

However, in the bonding layer breaking step (S30) of the second embodiment, after the position of the holding jig 42 is adjusted in such a manner that the plural prisms 11-1, 11-2, and 11-3 and the plural recess parts 42c1, 42c2, and 42c3 are along the X-axis direction, the bonding layer 13b is irradiated with the laser beam L. In particular, in the bonding layer breaking step (S30) of the second embodiment, when irradiation with the laser beam L is carried out along the X-axis direction, the respective ranges from one side 11b1 to one side 11c1 of the prism 11-1, from one side 11b2 to one side 11c2 of the prism 11-2, and from one side 11b3 to one side 11c3 of the prism 11-3 are sequentially irradiated with the laser beam L.

Due to this, by one time irradiation with the laser beam L along the X-axis direction, the bonding layer 13b in the range corresponding to each one surface 11a of the plural prisms 11-1, 11-2, and 11-3 can be broken. Consequently, the production volume of the prism 11 with the optical thin film 13a per unit time can be improved compared with the first embodiment. Besides, structure, method, and so forth according to the above-described embodiments can be carried out with changes as appropriate without departing from the scope of the object of the present invention.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A method for forming an adherend with an optical thin film through sticking the optical thin film to the adherend, the method comprising:
a substrate preparation step of preparing a substrate over which the optical thin film is formed with intermediary of a bonding layer;
a sticking step of sticking the adherend with lower heat resistance compared with quartz glass to a side of the optical thin film of the substrate after the substrate preparation step;
a bonding layer breaking step of breaking the bonding layer through carrying out irradiation with a laser beam with such a wavelength as to be transmitted through the substrate and be absorbed by the bonding layer from a surface of the substrate on an opposite side to a surface over which the optical thin film is formed after the sticking step; and
a separating step of separating the adherend to which the optical thin film is stuck and the substrate after the bonding layer breaking step.

2. The method for forming an adherend with an optical thin film through sticking the optical thin film to the adherend according to claim 1, wherein the adherend is formed of a resin.
